(19) United States
(12) Patent Application Publication
(10) Pub. No.: US 2008/0149473 A1
(43) Pub. Date: Jun. 26, 2008

(54) MAGNETRON SPUTTERING APPARATUS

(75) Inventor: Naruo AJIMA, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC ELECTRONICS CORPORATION, Kanagawa (JP)

(21) Appl. No.: 11/928,506

(22) Filed: Oct. 30, 2007

(30) Foreign Application Priority Data
Dec. 26, 2006 (JP) 2006-350601

(51) Int. Cl. C23C 14/35

(52) U.S. Cl. 204/192.12; 204/298.16

(57) ABSTRACT

A magnetron sputtering apparatus includes a target, a substrate holder, a magnetic field generator and a driving device. The substrate holder is arranged in front of the target. The magnetic field generator is arranged in back of the target. The driving device moves the magnetic field generator between a first position and a second position. The second position is closer to the target than the first position. The magnetic generator is arranged at the first position during a thin film formation. Repeated thin film formation may induce a sputtering particle to grow to be a lump on the target. If the lump is not removed from the target, the lump may fall on a substrate on the substrate holder. During cleaning of the target, the magnetic field generator is arranged at the second position and generates magnetic field to remove the lump from the target.

### BACKGROUND OF THE INVENTION

1. Field of the Invention

The present invention relates to a magnetron sputtering apparatus and a thin film manufacturing method.

2. Description of Related Art

A magnetron sputtering apparatus is used for forming a thin film in a process for manufacturing a semiconductor device. There has been known a planar magnetron sputtering apparatus as one of magnetron sputtering apparatuses.

FIG. 1 is a cross-sectional view of a planar magnetron sputtering apparatus according to related art. The magnetron sputtering apparatus 401 includes a film forming chamber 402, a substrate holder 403, a shielding plate 404, a rotating mechanism 405, a target 407, a back plate 408, a matching box 409, an RF (Radio Frequency) power supply 410 and a magnet unit 411. The film forming chamber 402 includes an inlet port 406 and an outlet port 420, and is grounded. The substrate holder 403, the shielding plate 404 and the target 407 are provided inside of the film forming chamber 402. The substrate holder 403 is arranged in front of the target 407 and faces the target 407. The substrate holder 403 is grounded via a capacitor. The rotating mechanism 405 is provided outside of the film forming chamber 402, and rotates the substrate holder 403. The target 407 is sintered on the back plate 408, and further, is grounded via the matching box 409 and the RF power supply 410. The RF power supply 410 applies RF power to the target 407 via the matching box 409. The magnet unit 411 is arranged in back of the target 407. The magnet unit 411 generates magnetic fields 413a and 413b between the target 407 and the substrate holder 403. A center line S11 extends through the centers of the substrate holder 403 and the target 407. The center line S11 is parallel to a direction in which the target 407 and the substrate holder 403 face each other.

Explanation will be made below on a thin film manufacturing method by the use of the magnetron sputtering apparatus 401. A substrate W is mounted on the substrate holder 403. The film forming chamber 402 is evacuated through the outlet port 420 such that a pressure therein ranges from 10⁻⁴ Pa to 10⁻⁵ Pa. The RF power supply 410 applies RF power between the target 407 and the ground while argon gas as sputtering gas is supplied into the film forming chamber 402 through the inlet port 406, thereby inducing plasma in the film forming chamber 402. Then, the argon gas is ionized and the resultant ion is accelerated due to self bias to collide against the target 407. An impact caused by the collision allows an atom at a surface of the target 407 to fly out as a sputtering particle 414 which adheres to a surface of the substrate W. Atoms of the target 407 fly out as the sputtering particles 414, and then, are deposited on the surface of the substrate W, thus a thin film is formed on the substrate W. Here, the magnetic fields 413a and 413b induce cycloid motions of secondary electrons from the target 407, thereby increasing a frequency of ionization collisions between the electrons and the argon gas. In this manner, plasmas 412a and 412b are produced near the target 407, thus increasing a film forming rate (a sputtering rate).

As for the magnetron sputtering apparatus 401, a uniform magnetic field cannot be generated over the entire target 407, and therefore, the target 407 locally erodes. FIG. 2 is a cross-sectional view of the target 407. Since the numerous sputtering particles 414 fly from a portion of the target 407 facing a strong portion of the magnetic field 413a or 413b, the portion of the target 407 relatively deeply erodes, and therefore, is referred to as an erosion region 428. In contrast, since few sputtering particles 414 fly from a portion of the target 407 facing a weak portion of the magnetic field 413a or 413b, the portion of the target 407 relatively shallowly erodes, and therefore, is referred to as a non-erosion region 429. The non-erosion region 429 tends to be formed in the center of the target 407 (through which the center line S11 extends). In the contrast, the erosion region 428 tends to be formed around the center. Since the erosion region 428 more deeply erodes than the non-erosion region 429, a sputtering particle flying from the erosion region 428 may adhere not to the substrate W but to the non-erosion region 429 in some case. The sputtering particle adhering to the non-erosion region 429 grows to be a lump. The lump may be referred to as a product. If the lump is released from the target 407 for some reason, it falls as a particle on the substrate W. A probability of the release of the lump from the target 407 increases in accordance with an increase in the times of formation of the thin film. Therefore, the film forming chamber 402 needs be periodically released to the atmosphere in order to remove the lump. The removal of the lump must be performed more frequently than a normal maintenance in which the film forming chamber 402 is released to the atmosphere. For example, the normal maintenance is performed for replacing the shielding plate 404. However, the frequent release of the film forming chamber 402 to the atmosphere reduces the productivity of thin film formation by the magnetron sputtering apparatus 401.

In order to solve the above-described problems, there has been developed a technique. In the technique, a magnet unit is rotated to generate magnetic field which is uniform in time average, and thus, a target uniformly erodes. Japanese Laid Open Patent Application (JP-A-Heisei, 11-6062) discloses one example of the technique. FIG. 3 schematically shows a magnetron sputtering apparatus 201 disclosed in Japanese Laid Open Patent Application (JP-A-Heisei, 11-6062). The magnetron sputtering apparatus 201 includes a film forming chamber 202, a substrate holder 203, a shield 204, a target 207, a back plate 208, a magnet unit 211 and a rotating means 221. The substrate holder 203 and the target 207 are provided inside of the film forming chamber 202. The substrate holder 203 is arranged in front of the target 207 and faces the target 207. The shield 204 partitions the inside of the film forming chamber 202 into a space on the side of the target 207 and a space on the side of the substrate holder 203, and has an opening through which the substrate W mounted on the substrate holder 203 faces the target 207. The target 207 is sintered on the back plate 208. The magnet unit 211 is arranged in back of the target 207 and mounted to the rotating means 221. The rotating means 221 includes a motor 223 and a rotating shaft 222 to which the magnet unit 211 is fixed. A pulley 225 is mounted to an output shaft 224 of the motor 223. The rotation of the pulley 225 is transmitted via a belt 226 to the rotating shaft 222. The magnet unit 211 is rotated by the motor 223.

Explanation will be made below on a thin film manufacturing method by the use of the magnetron sputtering apparatus 201. At first, magnetic field crossing electric field is generated over substantially the entire target 207 by rotating the magnet unit 211, and thus, plasma 212 of high density is produced in the vicinity of the target 207 to perform sputtering for a predetermined period of time. Thereafter, another sputtering is performed in which a rotational center of the magnet unit 211 is displaced from that for the preceding sputtering. The preceding sputtering and the following sputtering are different in a strength distribution of the magnetic field from each other. As a consequence, a sputtering particle adhering to the target 207 during the preceding sputtering or a lump grown from the sputtering particle is supplied in forming a thin film on the substrate W during the following sputtering. In the magnetron sputtering apparatus 201, since the film forming chamber 202 need not be released periodically to the atmosphere in order to remove the lump adhering to the target 207, it is possible to prevent a reduction of productivity of thin film formation by the use of the magnetron sputtering apparatus 201.

Japanese Laid Open Patent Application (JP-A-Heisei, 4-154966) discloses one example of another technique in which an erosion region of a target is enlarged without rotating a magnet unit. FIG. 4 schematically shows a magnetron sputtering apparatus 301 disclosed in Japanese Laid Open Patent Application (JP-A-Heisei, 4-154966). The magnetron sputtering apparatus 301 includes a film forming chamber 302, a first electrode 303, a permanent magnet unit 304, a target 307, a second electrode 308, a shutter 332 and a power supply 310. The film forming chamber 302 includes an inlet port 306 and an outlet port 320. The outlet port 320 is connected to a pump (not shown) for evacuating the film forming chamber 302. Argon gas as sputtering gas is supplied into the film forming chamber 302 through the inlet port 306. The target 307, the first electrode 303 and the shutter 332 are provided inside of the film forming chamber 302. The first electrode 303 is arranged in front of the target 307 and faces the target 307. The shutter 332 is arranged between the target 307 and the first electrode 303. The target 307 is provided on the second electrode 308. The first electrode 303 and the second electrode 308 are connected to each other via the power supply 310. The power supply 310 applies DC (Direct Current) voltage or radio frequency voltage between the first electrode 303 and the second electrode 308. The permanent magnet unit 304 is arranged in back of the target 307. The permanent magnet unit 304 includes peripheral magnets 311a, a center magnet 311b, a supporting member 333, guides 334, springs 335, a driving device 336 and a pusher 337. The guides 334 are arranged on a ring. The peripheral magnet 311a and the center magnet 311b are arranged such that their polarities are contrary to each other. The center magnet 311b is fixed to the supporting member 333 and faces the center of the target 307. Each of the guides 334 is supported by the supporting member 333 such that the guide 334 freely slides inward and outward in a radial direction. Here, the radial direction is along a plane perpendicular to a center line S12 and a center of the radial direction is an intersection between the plane and the center line S12. The center line S12 extends through the center of the target 307 and is parallel to a direction in which the target 307 and the first electrode 303 face each other. The peripheral magnets 311a are fixed to the guides 334, respectively. The springs 335 are arranged outside the guides 334, respectively, and, each of the spring 335 biases the corresponding guide 334 inward in the radial direction. The driving device 336 moves the pusher 337 along the center line S12. Since the pusher 337 has a conical surface which contacts the guides 334, the guides 334 moves inward and outward in the radial direction in association with a linear motion of the pusher 337 along the center line S12. The diameter of the ring, on which the guides 334 are arranged, decrease and increases in association with the inward and outward motion of the guides 334. Thus, each of the peripheral magnets 311a moves inward and outward in the radial direction in association with the decrease and increase in the diameter of the ring of the guides 334.

Explanation will be made below on a thin film manufacturing method by the use of the magnetron sputtering apparatus 301. At first, a substrate W mounted on the first electrode 303 is subjected to a film forming process in a condition that each of the peripheral magnets 311a is arranged near the center of the radial direction. In this case, the permanent magnet unit 304 generates magnetic fields 313a and 313b in the vicinity of the center of the target 307. Upon the completion of the film formation, the shutter 332 closes, and then, the substrate W is replaced with another substrate. During this replacement, the target 307 is cleaned in a condition that the peripheral magnets 311a are arranged far from the center of the radial direction. Since the magnetic field of broader distribution is generated during the cleaning than during the film formation, the non-erosion region of the target 307 during the film formation erodes, and thus, is cleaned.

The techniques disclosed in Japanese Laid Open Patent Applications (JP-A-Heisei, 11-6062) and (JP-A-Heisei, 4-154966) enable the lump to be removed from the target without releasing the film forming chamber to the atmosphere. However, the present inventor has recognized that the following problems remain unsolved.

In the technique disclosed in Japanese Laid Open Patent Application (JP-A-Heisei, 11-6062), the rotation of the magnet unit 211 may largely increase the fluctuation of condition of the plasma 212. The fluctuation of condition of the plasma 212 may not cause serious problems in a moderate-precision film formation to form, for example, electrode metal, but cause serious problems in a high-precision film formation to form, for example, an insulating film as multilayer optical thin film. It is necessary to suppress variation in index of refraction dew to variation of a film quality of the insulating film as multilayer optical thin film. Here, the film quality refers to the condition of a film determined from the distribution of amorphous structures or columnar structures in the cross section of the film. The film quality is liable to be influenced by the rate of the film formation. The fluctuation of condition of the plasma 212 unfavorably varies the rate of the film formation.

In the technique disclosed in Japanese Laid Open Patent Application (JP-A-Heisei, 4-154966), the center magnet 311b is fixed in back of the center of the target 307. Since lines of magnetic force extend from a north pole to a south pole, the magnetic field crossing the electric field is weak in the vicinity of the center of the target 307 in both of the film forming and the cleaning. As a consequence, even if the cleaning is performed, it is difficult to remove the lump from the target 307.

### SUMMARY

In one embodiment, a magnetron sputtering apparatus includes a target, a substrate holder, a first magnetic field generator and a first driving device. The substrate holder is arranged in front of the target. The first magnetic field generator is arranged in back of the target. The first driving device moves the first magnetic field generator between a first position and a second position. The second position is closer to the target than the first position.

In another embodiment, a magnetron sputtering apparatus includes a target, a means for holding a substrate, a means for generating magnetic field and a means for moving the means for generating magnetic field between a first position and a second position in back of the target. The means for holding the substrate is arranged in front of the target. The second position is closer to the target than the first position.

In further another embodiment, a thin film manufacturing method includes: forming a thin film on a substrate mounted on a substrate holder in front of a target when a first magnetic field generator is arranged at a first position in back of the target; and cleaning the target when the first magnetic field generator is arranged at a second position in back of the target. The second position is closer to the target than the first position.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view of a magnetron sputtering apparatus according to related art;

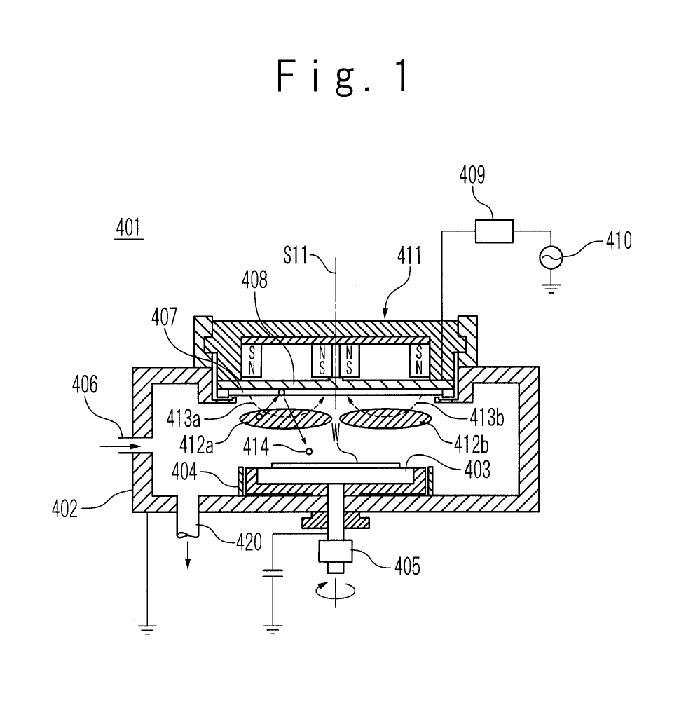

FIG. 2 is a cross-sectional view of a target of the magnetron sputtering apparatus of FIG. 1;

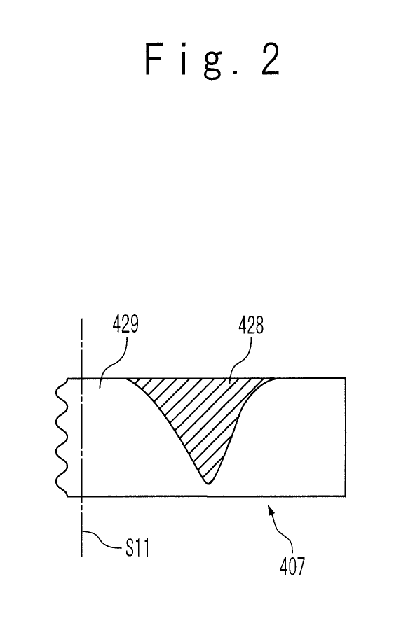

FIG. 3 is a cross-sectional view of a conventional magnetron sputtering apparatus;

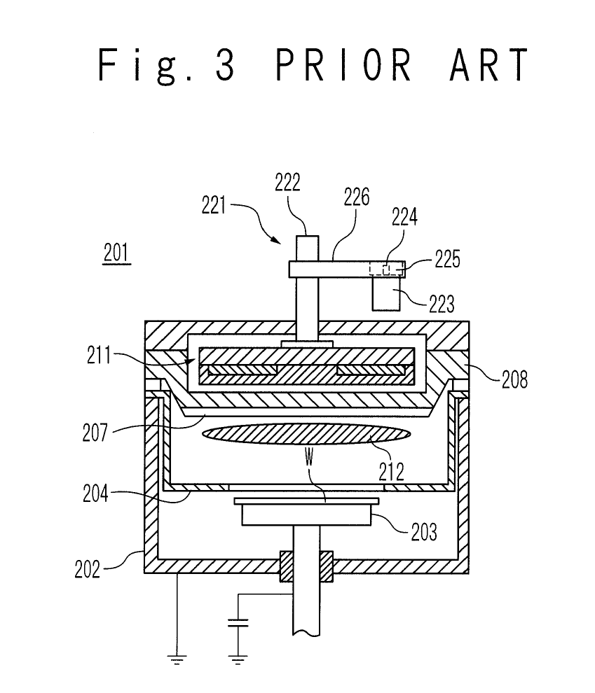

FIG. 4 is a cross-sectional view of another conventional magnetron sputtering apparatus;

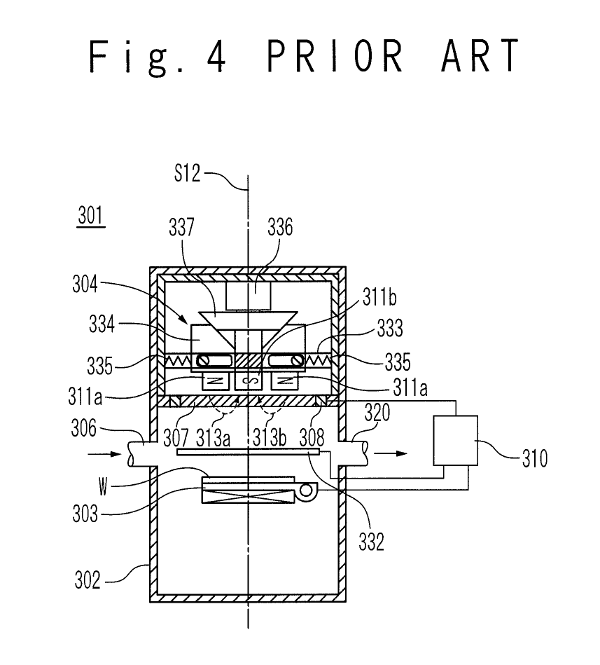

FIG. 5 is a cross-sectional view of a magnetron sputtering apparatus according to a first embodiment of the present invention, when the magnetron sputtering apparatus forms a thin film on a substrate;

FIG. 6 is a cross-sectional view of the magnetron sputtering apparatus according to the first embodiment, when a lump (i.e., a product) is removed from a target of the magnetron sputtering apparatus; and

FIG. 7 is a top view of the magnetron sputtering apparatus according to the first embodiment.

### DETAILED DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

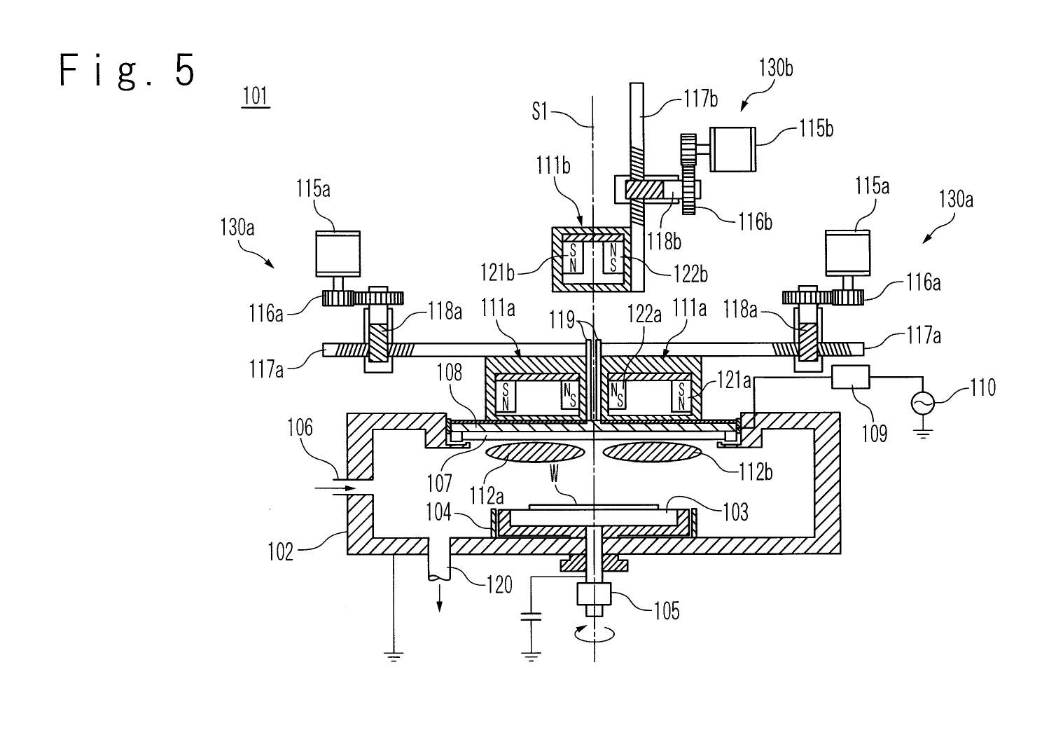

FIG. 5 is a cross-sectional view of a magnetron sputtering apparatus 101 according to a first embodiment of the present invention. FIG. 5 schematically shows the magnetron sputtering apparatus 101 when the magnetron sputtering apparatus 101 forms a thin film through sputtering.

The magnetron sputtering apparatus 101 includes a film forming chamber 102, a substrate holder 103, a shielding plate 104, a rotating mechanism 105, a target 107, a back plate 108, a matching box 109, an RF power supply 110, magnetic field generators 111a, a magnetic field generator 111b, driving devices 130a and a driving device 130b. Here, the magnetic field generators 111a and the magnetic field generator 111b are referred to also as magnet units 111a and a magnet unit 111b, respectively. The film forming chamber 102 includes an inlet port 106 and an outlet port 120, and is grounded. The substrate holder 103, the shielding plate 104 and the target 107 are provided inside of the film forming chamber 102. The substrate holder 103 is arranged in front of the target 107 and faces the target 107. A center line S1 is a straight line which extends through the centers of the substrate holder 103 and the target 107 and is parallel to a direction in which the substrate holder 103 and the target 107 face each other. The rotating mechanism 105 is provided outside of the film forming chamber 102 and rotates the substrate holder 103 around the center line S1. The substrate holder 103 is grounded via a capacitor. The target 107 is sintered on the back plate 108, and further, is grounded via the matching box 109 and the RF power supply 110. The RF power supply 110 applies RF power to the target 107 via the matching box 109. Each of the magnetic field generators 111a is arranged in back of the target 107. The magnetic field generators 111a are arranged on a ring and the axis of the ring is the center line S1. One driving device 130a is provided for each of magnetic field generators 111a. Each of the driving devices 130a includes a motor 115a, a gear 116a, a rack 117a and a pinion 118a. The rotation of the motor 115a is transmitted to the pinion 118a via the gear 116a, to be converted into a linear motion of the rack 117a having the magnetic field generator 111a fixed thereto. The driving device 130a moves the corresponding magnetic field generator 111a inward and outward in a radial direction. Here, the radial direction is along a plane perpendicular to the center line S1 and a center of the radial direction is an intersection between the plane and the center line S1. In other words, the driving device 130a moves the corresponding magnetic field generator 111a along a back surface of the target 107 between the center and outside of the target 107. The driving device 130a moves the corresponding magnetic field generator 111a along a straight line perpendicular to the center line S1. Each of the magnetic field generators 111a includes a magnet shield 119 and magnets 121a and 122a. For example, the magnet shield 119 is preferably made of permalloy having a highest magnetic permeability out of metals. The magnet shield 119 is arranged at a center side of the magnetic field generator 111a. The center side is oriented toward the center line S1. The magnet 122a is arranged outside of the magnet shield 119 with respect to the radial direction. The magnet 121a is arranged outside of the magnet 122a with respect to the radial direction. A south pole of the magnet 122a is oriented toward the target 107 and a north pole of the magnet 122a is oriented toward opposite to the target 107. In contrast, a north pole of the magnet 121a is oriented toward the target 107 and a south pole of the magnet 121a is oriented toward opposite to the target 107. The magnetic field generator 111b is arranged on the center line S1 in back of the target 107. The magnetic field generator 111b includes magnets 121b and 122b. The magnets 121b and 122b face each other on both sides of the center line S1. A north pole of the magnet 121b is oriented toward the target 107 and a south pole of the magnet 121b is oriented toward opposite to the target 107. In contrast, a south pole of the magnet 122b is oriented toward the target 107 and a north pole of the magnet 122b is oriented toward opposite to the target 107. The driving device 130b includes a motor 115b, a gear 116b, a rack 117b and a pinion 118b. The rotation of the motor 115b is transmitted to the pinion 118b via the gear 116b, to be converted into a linear motion of the rack 117b having the magnetic field generator 111b fixed thereto. The driving device 130b moves the magnetic field generator 111b along the center line S1.

Explanation will be made below on a thin film manufacturing method by the use of the magnetron sputtering apparatus 101. As shown in FIG. 5, the magnetic field generators 111a are arranged near the center line S1, and further, the magnetic field generator 111b is arranged on the center line S1 more remotely from the target 107 than the magnetic field generators 111a. In the arrangements, a position of the magnetic field generator 111a is referred to as an inside position: in contrast, a position of the magnetic field generator 111b is referred to as an upside position. A substrate W such as a semiconductor wafer is mounted on the substrate holder 103. The film forming chamber 102 is evacuated through the outlet port 120 such that a pressure therein ranges from 10⁻⁴ Pa to 10⁻⁵ Pa. The RF power is applied between the target 107 and the ground by the use of the RF power supply 110 while supplying argon gas as sputtering gas into the film forming chamber 102 through the inlet port 106, thereby inducing plasma in the film forming chamber 102. At this time, electric field is produced between the target 107 and the substrate holder 103. And then, the argon gas is ionized and the resultant ion is accelerated due to self bias to collide against the target 107. An impact caused by the collision allows an atom at the surface of the target 107 to fly out as a sputtering particle which adheres to a surface of the substrate W. Atoms of the target 107 fly out as the sputtering particles, and then, are deposited on the substrate W, thus forming a thin film. Here, the magnetic field generators 111a generate magnetic fields between the target 107 and the substrate holder 103. The magnetic fields induce cycloid motions of secondary electrons from the target 107, thereby increasing a frequency of ionization collisions between the electrons and the argon gas. In this manner, plasmas 112a and 112b of high density are produced near the target 107, thus increasing a film forming rate (a sputtering rate).

Since the magnetic field generators 111a and 111b are not rotated but fixed during the film formation by the magnetron sputtering apparatus 101, there occur no fluctuations of conditions of the plasmas 112a and 112b. Therefore, the sputtering (the film formation) can be performed in the condition that density distributions of the plasmas are stable. The magnetron sputtering apparatus 101 is applicable to a high-precision film formation to form, for example, multilayer optical thin film.

The repeated film formation forms a non-erosion region at the center of the target 107 and forms an erosion region around the non-erosion region. A sputtering particle adheres to the non-erosion region, and then, grows to be a lump (a product). If the lump remains not removed, the lump may fall as a particle on the substrate W. Therefore, the target 107 is cleaned in order to remove the lump.

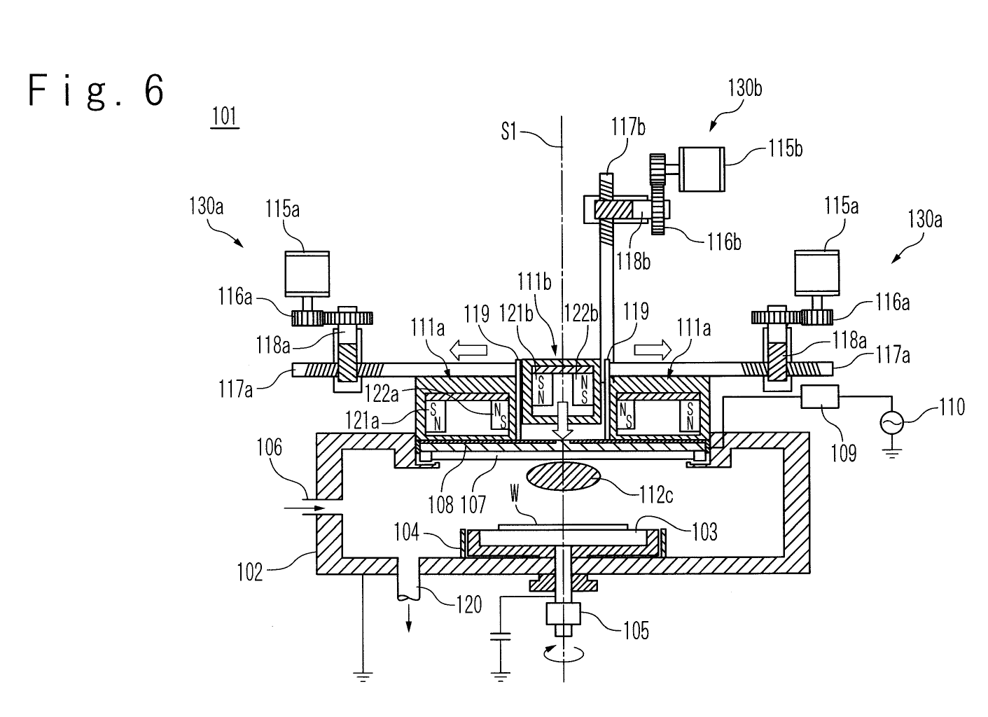

FIG. 6 shows the magnetron sputtering apparatus 101 when the target 107 is cleaned. After the film formation is repeated predetermined times or after the cumulative time for the film formation exceeds a predetermined time, the driving device 130a moves the magnetic field generators 111a toward outside with respect to the radial direction and the driving device 130b moves the magnetic field generator 111b toward the target 107. The target 107 is cleaned in a condition that each of the magnetic field generators 111a is fixed at an outside position far from the center line S1 along the radial direction than the inside position and the magnetic field generator 111b is fixed at a downside position closer to the target 107 than the upside position. Here, the magnetic field generator 111b is arranged in a space from which the magnetic field generators 111a have moved. A dummy substrate is mounted on the substrate holder 103. The film forming chamber 102 is evacuated through the outlet port 120 such that a pressure therein ranges from 10⁻⁴ Pa to 10⁻⁵ Pa. The RF power is applied between the target 107 and the ground by the use of the RF power supply 110 while supplying argon gas as sputtering gas into the film forming chamber 102 through the inlet port 106, thereby inducing the plasma in the film forming chamber 102. At this time, an electric field is produced between the target 107 and the substrate holder 103. And then, the argon gas is ionized and the resultant ion is accelerated due to self bias to collide against the target 107. Here, the magnetic field generator 111b generates magnetic field between the target 107 and the substrate holder 103. The magnetic field induces cycloid motions of secondary electrons from the target 107, thereby increasing a frequency of ionization collisions between the electrons and the argon gas. In this manner, plasma 112c of high density is produced in the vicinity of the center of the target 107, thus removing the lump adhering to the center of the target 107. The composition of the sputtering gas during both of the film formation and the cleaning may be identical to or different from each other.

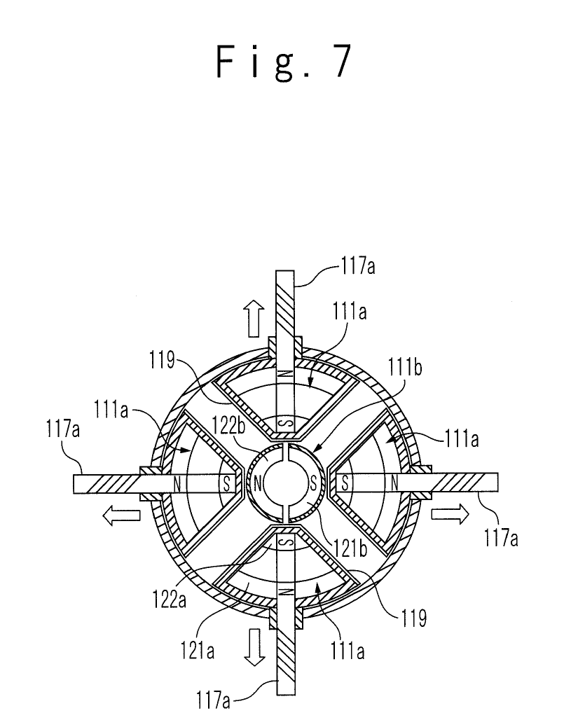

FIG. 7 shows an arrangement of the magnetic field generators 111a and 111b as viewed in a direction parallel to the center line S1 when the target 107 is cleaned. The target 107 is cleaned in a condition that the magnetic field generators 111a are sufficiently remote from the center line S1, the magnetic fields generated by the magnetic field generators 111a have no or little influence on the sputtering particles flying from the target 107, and thus, preventing the sputtering particles adhering to other than the dummy substrate. Moreover, the magnet shields 119 arranged at the center side of the magnetic field generator 111a enables that only the center of the target 107 is sputtered without interference by the magnetic field generated by the magnetic field generator 111a. The magnet shield 119 also covers a lateral side of the magnetic field generator 111a (a side oriented toward the neighboring magnetic field generator 111a), thus preventing interference between the magnetic field generated by one of the magnetic field generators 111a and the magnetic field generated by the other magnetic field generator 111a during the film formation.

Since the lump adhering to the center of the target 107 can be removed without releasing the film forming chamber 102 to the atmosphere, the magnetron sputtering apparatus 101 provides a superior productivity. In addition, it is possible to elongate the interval between maintenances in which the film forming chamber 102 is released to the atmosphere.

Additionally, the magnetic field generator 111b includes the magnets 121b and 122b, thus securely generating the magnetic field between the target 107 and the substrate holder 103 such that the magnetic field crosses the electric field.

Each of the magnets 121a, 121b, 122a and 122b may be a permanent magnet or an electromagnet. The magnetic field generator 111b is arranged at the upside position remote from the target 107 during the thin film formation, thus preventing the magnetic field generated by the magnetic field generator 111b from adversely influencing on the thin film formation even if the magnets 121b and 122b are permanent magnets.

It is apparent that the present invention is not limited to the above embodiments, but may be modified and changed without departing from the scope and spirit of the invention.

It should also be noted that this application is based upon and claims the benefit of priority from Japanese patent application No. 2006-350601, filed on Dec. 26, 2006, the disclosure of which is incorporated herein in its entirely by reference.

What is claimed is:

1. A magnetron sputtering apparatus comprising:
a target;
a substrate holder arranged in front of said target;
a first magnetic field generator arranged in back of said target; and
a first driving device configured to move said first magnetic field generator between a first position and a second position,
wherein said second position is closer to said target than said first position.

2. The magnetron sputtering apparatus according to claim 1, further comprising:
a second magnetic field generator arranged in back of said target; and
a second driving device,
wherein said first driving device is configured to move said first magnetic field generator along a first straight line parallel to a direction in which said target and said substrate holder face each other,
said second driving device is configured to move said second magnetic field generator along a second straight line perpendicular to said first straight line,
said second magnetic field generator includes a magnet shield arranged at a side of said second magnetic field generator, and
said side is oriented toward said first straight line.

3. The magnetron sputtering apparatus according to claim 1, wherein said first magnetic field generator includes a first magnet and a second magnet,
a north pole of said first magnet is oriented toward said target, and
a south pole of said second magnet is oriented toward said target.

4. A magnetron sputtering apparatus comprising:
a target;
a means for holding a substrate;
a means for generating magnetic field; and
a means for moving said means for generating magnetic field between a first position and a second position in back of said target,
wherein said means for holding said substrate is arranged in front of said target, and
said second position is closer to said target than said first position.

5. A thin film manufacturing method comprising:
forming a thin film on a substrate mounted on a substrate holder in front of a target when a first magnetic field generator is arranged at a first position in back of said target; and
cleaning said target when said first magnetic field generator is arranged at a second position in back of said target,
wherein said second position is closer to said target than said first position.

6. The thin film manufacturing method according to claim 5, further comprising:
moving said first magnetic field generator between said first position and said second position.

7. The thin film manufacturing method according to claim 6, further comprising:
moving a second magnetic field generator in back of said target,
wherein in said moving said first magnetic field generator, moving said first magnetic field generator along a first straight line parallel to a direction in which said target and said substrate holder faces each other,
in said moving said second magnetic field generator, moving said second magnetic field generator along a second straight line perpendicular to said first straight line,
said second magnetic field generator includes a magnet shield arranged at a side of said second magnetic field generator, and
said side is oriented toward said first straight line.

8. The thin film manufacturing method according to claim 7, wherein said forming said thin film comprises:
supplying sputtering gas into a film forming chamber in which said target and said substrate holder are provided;
applying voltage to said target; and
said second magnetic field generator generating magnetic field between said target and said substrate holder, and
said cleaning said target comprises:
supplying sputtering gas into said film forming chamber;
applying voltage to said target; and
said first magnetic field generator generating magnetic field between said target and said substrate holder.
